(19) United States
(12) Patent Application Publication
(10) Pub. No.: US 2010/0122456 A1
(43) Pub. Date: May 20, 2010

(54) Integrated Alignment and Bonding System

(76) Inventors: Chen-Hua Yu, Hsin-Chu (TW); Wen-Chih Chiou, Miaoli (TW); Weng-Jin Wu, Hsin-Chi (TW)

Correspondence Address: SLATER & MATSIL, L.L.P., 17950 PRESTON ROAD, SUITE 1000, DALLAS, TX, 75252, US

(21) Appl. No.: 12/272,404

(22) Filed: Nov. 17, 2008

(51) Int. Cl. H05K 3/30

(52) U.S. Cl. 29/834; 29/829; 29/832; 29/835

(57) ABSTRACT

A method for bonding includes providing a first die and a second die; scanning at least one of the first die and the second die to determine thickness variations of the at least one of the first die and the second die; placing the second die facing the first die with a first surface of the first die facing a second surface of the second die; aligning the first surface and the second surface parallel to each other using the thickness variations; and bonding the second die onto the first die. The step of aligning the first surface and the second surface includes tilting one of the first die and the second die.

### TECHNICAL FIELD

This invention relates generally to integrated circuit manufacturing processes, and more particularly to apparatuses and methods for bonding semiconductor dies onto wafers.

### BACKGROUND

With the evolving of semiconductor technologies, semiconductor dies are becoming increasingly smaller. However, more functions need to be integrated into the semiconductor dies. Accordingly, the semiconductor dies need to have increasingly greater numbers of I/O pads packed into smaller areas, and the density of the I/O pads rises quickly. As a result, the packaging of the semiconductor dies becomes more difficult, which causes the yield to be adversely affected.

Packaging technologies can be divided into two categories. One category is typically referred to as a wafer level package (WLP), wherein dies on a wafer are packaged before they are sawed. The WLP technology has some advantages, such as a greater throughput and a lower cost. Further, less under-fill and/or molding compound are needed. However, the WLP suffers from drawbacks. As aforementioned, the sizes of the dies are becoming increasingly smaller, and the conventional WLP can only be fan-in type packages, in which the I/O pads of each die are limited to a region directly over the surface of the respective die. With the limited areas of the dies, the number of the I/O pads is limited due to the limitation of the pitch of the I/O pads. If the pitch of the pads is to be decreased to incorporate more I/O pads on a die, solder bridges may occur. Additionally, under the fixed-ball-size requirement, solder balls must have a certain size, which in turn limits the number of solder balls that can be packed on the surface of a die.

In the other category of packaging, dies are sawed from wafers before they are packaged onto other wafers, and only “known-good-dies” are packaged. An advantageous feature of this packaging technology is the possibility of forming fan-out chip packages, which means the I/O pads on a die can be redistributed to a greater area than the die, and hence the number of I/O pads packed on the surfaces of the dies can be increased.

The bonding of dies to wafers includes dielectric-to-dielectric bonding (also referred to fusion bonding) and copper-to-copper bonding. FIG. 1 illustrates a dielectric-to-dielectric bonding scheme, in which top die 100 is bonded onto bottom die 200, wherein bottom die 200 may be a part of a wafer. Dielectric layer 102 in top die 100 is bonded to dielectric layer 202 in bottom die 200. In the case, top die 100 and bottom die 200 have thickness variations, when top die 100 is bonded onto bottom die 200, one side of top die 100 may be applied with a greater force then other sides, and hence the side(s) applied with the smaller force may not be bonded properly.

The similar situation may also occur with copper-to-copper bonding. Referring to FIG. 2, top die 300 is bonded onto bottom die 400 through the bonding between bond pads 304 and 404, which may contact each other directly, or bonded through a very thin layer of solder. It is realized that with the increasing down-scaling of integrated circuits, the gap G between dielectric layers 302 and 402 becomes increasingly smaller, and the surface total thickness variation becomes increasingly greater. This applies a stricter requirement to the uniformity in the application of the bond force. When top die 300 is bonded onto bottom die 400, the total thickness variation may cause one side of die 300 or 400 to be thicker than other sides. One side of top die 300 may thus be applied with a greater force than other sides, and hence the side applied with the smaller force again may not be bonded properly.

Conventionally, the above-discussed problems were solved by performing a post-contact leveling after the top die is bonded onto the bottom wafer. However, this incurs additional process steps and longer process time, and results in the reduction in throughput. Accordingly, what is needed in the art is a bonding system and methods for the bonding with a high throughput.

### SUMMARY OF THE INVENTION

In accordance with one aspect of the present invention, a method for bonding includes providing a first die and a second die; scanning at least one of the first die and the second die to determine thickness variations of the at least one of the first die and the second die; placing the second die facing the first die with a first surface of the first die facing a second surface of the second die; aligning the first surface and the second surface parallel to each other using the thickness variations; and bonding the second die onto the first die. The step of aligning the first surface and the second surface includes tilting one of the first die and the second die.

In accordance with another aspect of the present invention, a method for bonding dies includes providing a bottom wafer including first dies; providing second dies; scanning the bottom wafer to determine first thickness variations of the first dies; placing the second dies in a die tray; scanning the second dies in the die tray to determine second thickness variations of the second dies; picking up one of the second dies from the die tray; and moving the one of the second dies to over one of the first dies. The method further includes tilting at least one of the bottom wafer and the one of the second dies, so that the first surface of the one of the first dies is parallel to a second surface of the one of the second dies, wherein the first surface faces the second surface. The method further includes, after the first surface and the second surface are parallel to each other, bonding the one of the second dies to the one of the first dies.

In accordance with yet another aspect of the present invention, a method for bonding dies includes providing a first die and a second die; placing the first die on a stage; moving the second die to face the first die; tilting at least one of the first die and the second die to make a first surface of the first die facing and parallel to a second surface of the second die; moving the second die toward the first die while keeping the first surface of the first die parallel to the second surface of the second die; and bonding the second die to the first die.

In accordance with yet another aspect of the present invention, an apparatus for bonding dies includes a scanning system configured to scan thickness variations of a die; a control unit connected to the scanning system, the control unit being configured to collect the thickness variations; a bond head connected to the control unit; and a stage for mounting the die thereon. The control unit is configured to control at least one of the bond head and the stage to tilt.

In accordance with yet another aspect of the present invention, an apparatus for bonding a first die with a second die includes a control unit; a stage for mounting a wafer thereon, wherein the wafer includes the first die; and a bond head configured to pick up the second die. The control unit is connected to and configured to tilt at least one of the bond head and the stage to make a first surface of the first die parallel to a second surface of the second die.

The advantageous features of the present invention include greater throughput and improved reliability in the bonding of dies onto dies or wafers.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional dielectric-to-dielectric bonding, wherein dies are not properly bonded due to thickness variations in dies;

FIG. 2 illustrates a conventional copper-to-copper bonding, wherein dies are not properly bonded due to thickness variations in dies;

FIGS. 3A through 6 are top views and cross-sectional views of intermediate stages in a bonding process of the present application; and

FIG. 7 illustrates a scanning system deployed under a wafer to be scanned.

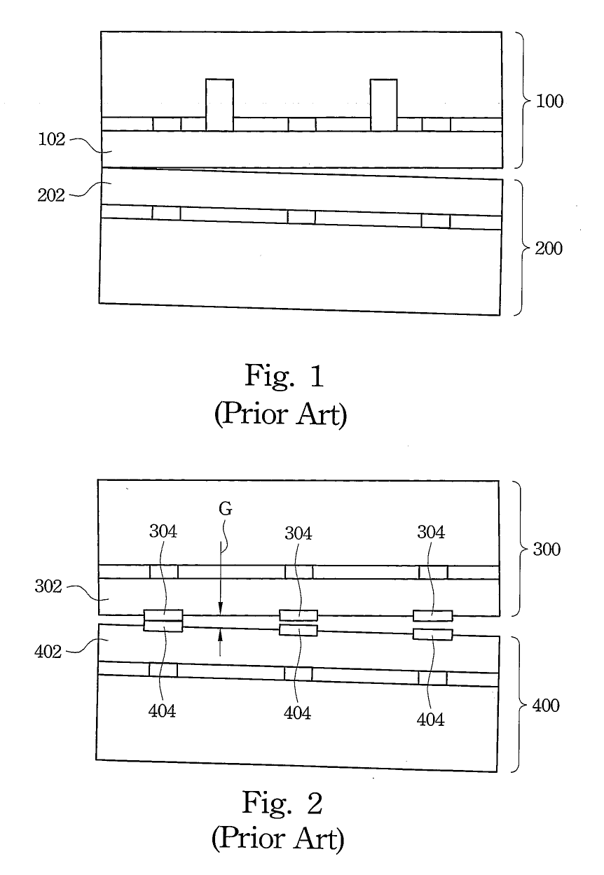

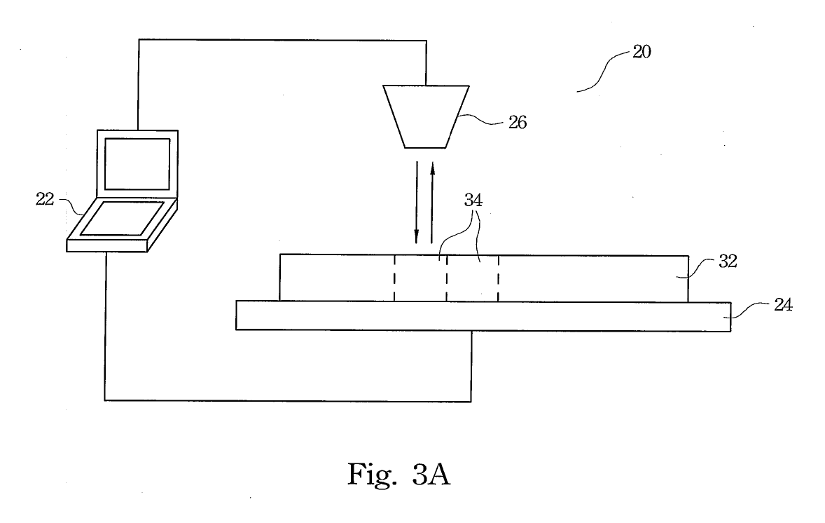

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel integrated aligning and bonding system and the methods for the bonding are provided. Throughout the various views and illustrative embodiments of the present invention, like reference numbers are used to designate like elements.

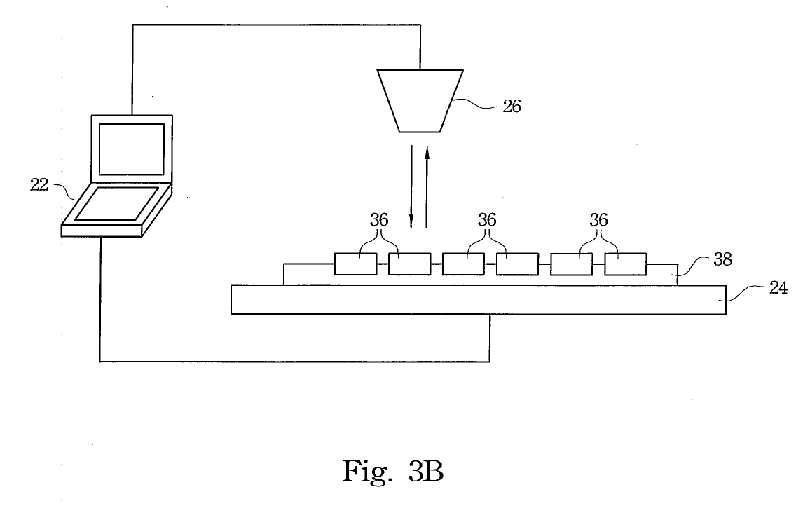

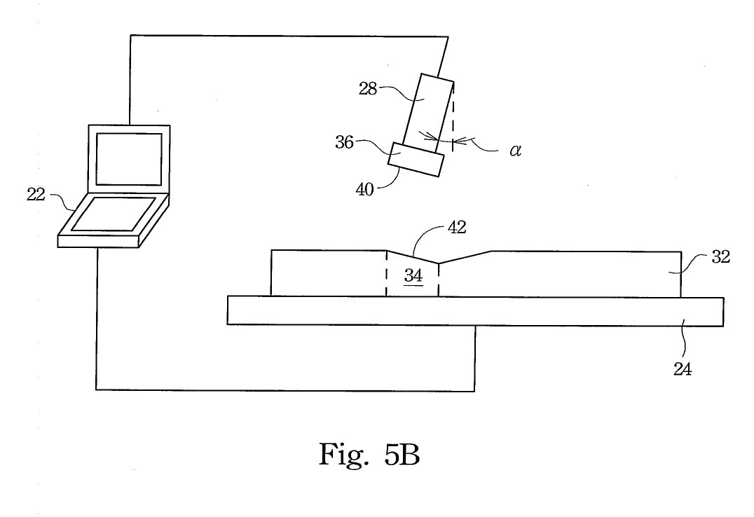

FIG. 3A schematically illustrates a part of bonding system 20, which includes control unit 22, stage 24, scanning system 26 and bond head 28 (not shown in FIG. 3A, refer to FIG. 5A). Preferably, stage 24, bond head 28, and scanning system 26 are in a controlled environment (not shown), which is capable of being filled with desirable gases including, for example, clean air, nitrogen, and/or the like. The controlled environment may also be a bonding chamber that can be vacuumed. Stage 24 may be an electro-static chuck (e-chuck), which is capable of mounting a wafer thereon, and increasing the temperature of the wafer to a desirable temperature for bonding.

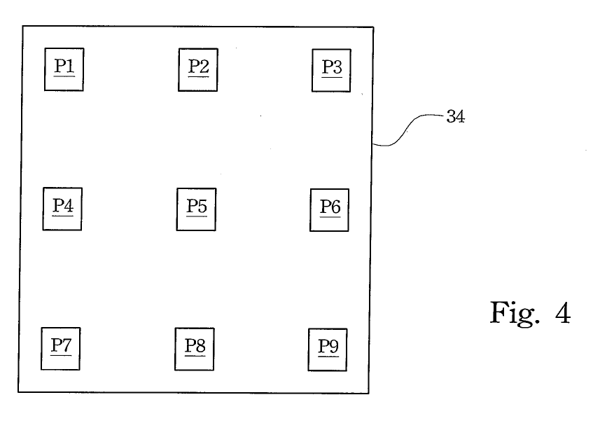

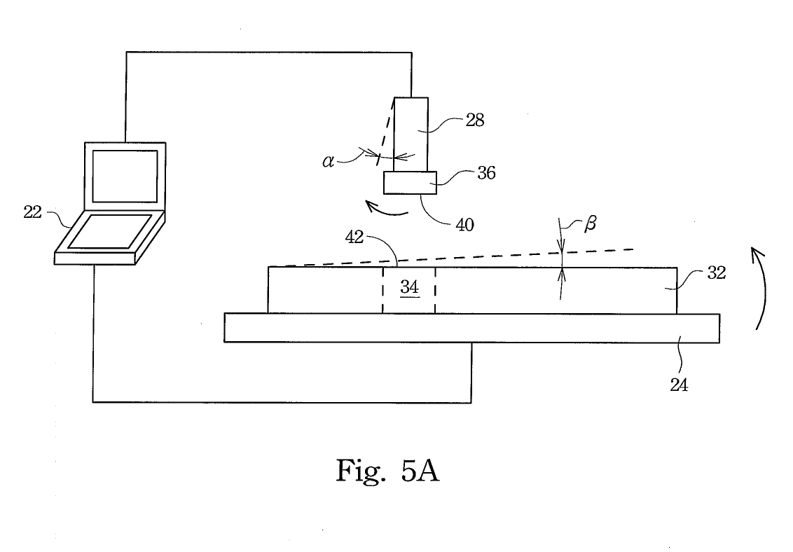

In FIG. 3A, bottom wafer 32 is loaded on stage 24. Scanning system 26 is then used to scan the surface of bottom wafer 32. In an embodiment, scanning system 26 is a laser system, which measures the distances between scanning system 26 and the scanned points on wafer 32, so that the thicknesses of bottom wafer 32 at the scanned points may be determined. The scan may be conducted line by line or point by point, with each bottom die 34 in bottom wafer 32 having multiple points scanned. FIG. 4 illustrates a top view of bottom die 34. In an exemplary embodiment, bottom die 34 has three rows and three columns of points scanned. The exemplary scanned points are indicated as P1 through P9, wherein each edge and each corner of bottom die 34 has at least one, and preferably more points scanned. With the thicknesses of points P1 through P9 of bottom die 34 being known, the thickness variations (topography) of bottom die 34 and bottom wafer 32 are known. The scanned data are stored in control unit 22 for subsequent bonding.

FIG. 3B illustrates the scanning of dies 36 that are to be bonded onto bottom wafer 32. Throughout the description, dies 36 are referred to as top dies although they may actually on the top or bottom when bonded. In an embodiment, top dies 36 are placed in die tray (or frame) 38. Die tray 38 is designed so that the surfaces contacting top dies 36 are leveled, and hence die tray 38 will not introduce thickness variations, which may be mistakenly construed as the thickness variations of top dies 36. Again, scanning system 26 scans top dies 36 to determine the surface topology, and hence the thickness variations of top dies 36. In an exemplary embodiment, the surface topologies may be determined, for example, by scanning nine points on each of top dies 36, which points are similar to what are shown in FIG. 4. Alternatively, scanning system 26 may perform a blanket scan line by line, and then extracting the thicknesses of dies from the blanket scan result. Top dies 36 and die tray 38 may also be placed over stage 24 to perform the scanning. The scanned data are stored in control unit 22.

FIG. 5A illustrates the bonding of one of the top dies 36 onto one of bottom dies 34. Bond head 28 is used to pickup one of top dies 36 from die tray 38, and move it to over bottom die 34. It is appreciated that the thickness variations of top die 36 and/or the thickness variation of bottom die 34 results in surface 40 of die 36 and surface 42 of die 34 to be unparallel to each other. As a result, if bond head 28 moves top die 36 down straightly, one side or one corner of top die 36 may touch the respective side or corner of bottom die 34 before other sides or corners. Accordingly, the side or corner that made contact first will be applied with a greater force than other sides or corners that make contact, and hence cold joints points are not bonded together) will be formed.

Since the thickness variation data of top die 36 and bottom die 34 are known to control unit 22, control unit 22 may compensate for the thickness variations in top die 36 and bottom die 34. In an embodiment, control unit 22 controls bond head 28 to slightly tilt by a small angle α, so that surface 40 of top die 36 is aligned parallel to surface 42 of bottom die 34. In alternative embodiments, stage 24, instead of bond head 28, is tilted by an angle β equal to angle α. In yet other embodiments, both stage 24 and bond head 28 are tilted to make surfaces 40 and 42 parallel to each other. FIG. 5B illustrates a tilted bond head 28. It is noted that the non-uniform thickness on bottom wafer 32 and the resulting tilt angle α may have been exaggerated in order to clearly show the concept of the present invention.

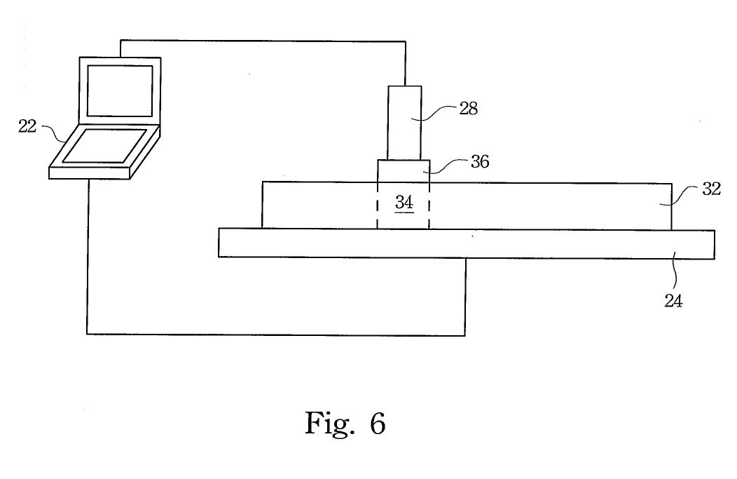

Next, bond head 28 is moved down (with surfaces 40 and 42 parallel to each other); so that surfaces 40 of top die 36 touch surface 42 of bottom die 34. It is appreciated that the tilting of stage 24 and/or bond head 28 may be performed any time before top die 36 touches bottom die 34. For example, the tilting of bond head 28 may be performed simultaneously with the downward motion of bond head 28. Due to the alignment action, all sides and corners of surfaces 40 and 42 make contact substantially simultaneously. For the bonding, a force is applied to press top die 36 and bottom die 34 against each other. With the non-uniform topology compensated for, the force applied to all sides and corners of top die 36 is substantially uniform. During the bonding, the temperature of bottom wafer 32 and/or top die 36 may be increased to desirable temperatures. The resulting structure after bonding is shown in FIG. 6. After the illustrated top die 36 is bonded onto bottom wafer 32, the remaining ones of dies 36 in die tray 38 (FIG. 3B) are bonded one by one onto bottom wafer 32, wherein the bonding of each of top dies 36 may adopt the above-discussed process. Since the thickness variations of all top dies 36 and bottom dies 34 are known by control unit 22, the compensation in the thickness variations may be performed for the bonding of each of the dies.

In the above-discussed embodiments, die-to-wafer bonding is discussed. In alternative embodiments, die-to-die bonding may be performed. The bonding process is essentially the same as discussed in the preceding paragraphs, except bottom dies may also be scanned when placed in a corresponding die tray. In yet other embodiments, wafer-to-wafer bonding is performed, in which both the bottom wafer and the top wafer are pre-scanned, and the topology of the bottom and top wafers are used for the alignment purpose.

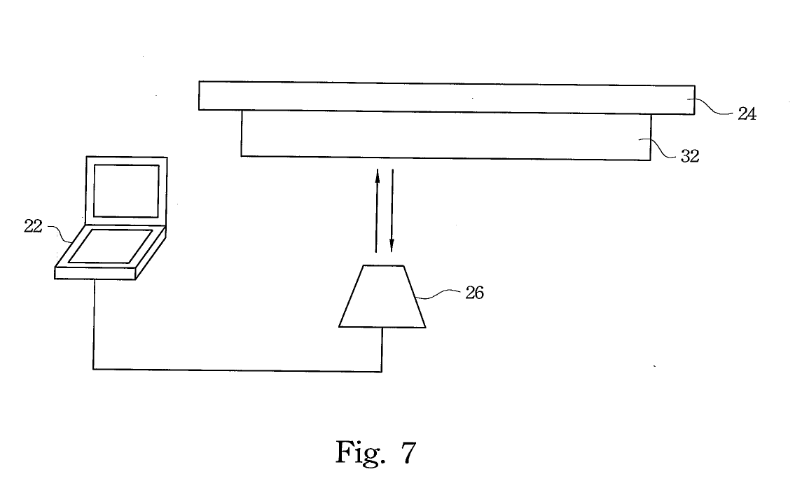

FIG. 7 illustrates an alternative embodiment, in which wafer 32 is mounted facing down, while scanning system 26 faces up to scan wafer 32. The bonding may be performed with wafer 32 facing down. Alternatively, after the scanning, wafer 32 is placed as shown in FIG. 3A, and then bonded.

The embodiments of the present invention have several advantageous features. With the thickness variation compensated for, the cold joint problem is at least reduced, and possibly substantially eliminated. By determining the surface topography of the dies and/or wafers to be bonded, the leveling and bonding may be performed at the same time, and hence there is no need to perform an additional leveling after the bonding process. The throughput is thus improved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for bonding, the method comprising:
providing a first die and a second die;
scanning at least one of the first die and the second die to determine thickness variations of the at least one of the first die and the second die;
placing the second die facing the first die with a first surface of the first die facing a second surface of the second die;
aligning the first surface and the second surface parallel to each other using the thickness variations; and
bonding the second die onto the first die.

2. The method of claim 1, wherein the step of aligning the first surface and the second surface comprises tilting at least one of the first die and the second die.

3. The method of claim 2, wherein the second die is a top die, and the first die is a bottom die, and wherein the step of tilting the at least one of the first die and the second die comprises tilting the top die.

4. The method of claim 2, wherein the second die is a top die, and the first die is a bottom die, and wherein the step of tilting the at least one of the first die and the second die comprises tilting the bottom die.

5. The method of claim 1, wherein the second die is a discrete die, and the first die is a portion of an un-sawed wafer.

6. The method of claim 5, wherein the step of scanning the at least one of the first die and the second die comprises scanning each of dies in the un-sawed wafer.

7. The method of claim 1, wherein the step of scanning the at least one of the first die and the second die comprises:
providing a die tray comprising a plurality of holding sites, each for holding a die;
placing the second die into a site of the die tray; and
scanning the second die.

8. The method of claim 7, wherein the die tray comprises a plurality of dies placed therein, and wherein the step of scanning the second die is a portion of a step of scanning all of the plurality of dies.

9. A method for bonding, the method comprising:
providing a bottom wafer comprising first dies;
providing second dies;
scanning the bottom wafer to determine first thickness variations of the first dies;
placing the second dies in a die tray;
scanning the second dies in the die tray to determine second thickness variations of the second dies;
picking up one of the second dies from the die tray;
moving the one of the second dies to over one of the first dies;
tilting at least one of the bottom wafer and the one of the second dies, so that a first surface of the one of the first dies is parallel to a second surface of the one of the second dies, wherein the first surface faces the second surface; and
bonding the one of the second dies to the one of the first dies.

10. The method of claim 9, wherein the step of scanning the bottom wafer and the step of scanning the second dies are performed by a scanning system, and wherein the method further comprises storing the first thickness variations and the second thickness variations in a control unit.

11. The method of claim 10, wherein the step of tilting is controlled by the control unit, and wherein the control unit uses the first thickness variations and the second thickness variations to make the first surface and the second surface parallel to each other.

12. The method of claim 9 further comprising bonding each of the second dies onto the first dies, with the first thickness variations and the second thickness variations used in the step of bonding each of the second dies to control tilting each pair of the first dies and the second dies.

13. The method of claim 9, wherein during the step of scanning the bottom wafer, each of the first dies has greater than about 9 points scanned, and during the step of scanning the second dies, each of the second dies has greater than about 9 points scanned.

14. A method for bonding, the method comprising:
providing a first die and a second die;
placing the first die on a stage;
moving the second die to face the first die;
tilting at least one of the first die and the second die to make a first surface of the first die facing and parallel to a second surface of the second die;
moving the second die toward the first die while keeping the first surface of the first die parallel to the second surface of the second die; and
bonding the second die to the first die.

15. The method of claim 14 further comprising, before the step of moving the second die, determining thickness variations of at least one of the first die and the second die.

16. The method of claim 15, wherein the step of determining the thickness variations of at least one of the first die and the second die comprises determining thickness variations of both the first die and the second die.

17. The method of claim 14, wherein the step of determining thickness variations is performed by scanning using laser.

18. The method of claim 14, wherein the first die is in a wafer, and the second die is a discrete die.

19. The method of claim 2, wherein during the step of tilting, a plane of a major surface of the at least one of the first die and the second die is tilted by an angle greater than zero degree.

20. The method of claim 19, wherein before the step of tilting, the major surface is in a first plane, and after the step of tilting, the major surface is in a second plane, and wherein the first plane is not parallel to the second plane.
